(19) United States
(12) Patent Application Publication
(10) Pub. No.: US 2020/0188898 A1
(43) Pub. Date: Jun. 18, 2020

(54) ANTIMONATE ELECTROCATALYST FOR AN ELECTROCHEMICAL REACTION

(71) Applicant: California Institute of Technology, Pasadena, CA (US)

(72) Inventors: Nathan S. Lewis, La Canada Flintridge, CA (US); Ivan A. Moreno-Hernandez, Pasadena, CA (US)

(21) Appl. No.: 16/718,014

(22) Filed: Dec. 17, 2019

Related U.S. Application Data
(60) Provisional application No. 62/780,435, filed on Dec. 17, 2018.

(51) Int. Cl. B01J 37/02; C25B 11/04; B01J 23/34; B01J 23/843; B01J 37/08; C23C 4/129; C23C 14/34; C23C 14/08; C25B 1/26; B01J 23/46

(52) U.S. Cl. CPC B01J 37/0228; C25B 11/0405; C25B 11/0468; C25B 11/0415; B01J 23/34; B01J 23/462; B01J 37/08; C23C 4/129; C23C 14/3464; C23C 14/08; C25B 1/26; B01J 23/8435

(57) ABSTRACT

Disclosed are stable, active non-precious metal oxide catalysts, such as transition metal antimonates (TMAs), for electrochemical reactions in harsh media conditions, such as the chlorine evolution reaction (CER). A disclosed electrocatalyst includes a metal oxide film containing a crystalline transition metal antimonite (TMA). The crystalline TMA may include NiSb₂Oₓ, CoSb₂Oₓ, or MnSb₂Oₓ. The metal oxide film may be formed on a conductive substrate, for example, a substrate including an antimony-doped tin oxide (ATO) film, using an annealing process.

### CROSS REFERENCE TO RELATED APPLICATIONS

This application claims the benefit of U.S. Provisional Patent Application Ser. No. 62/780,435, filed on Dec. 17, 2018, which is incorporated by reference herein in its entirety.

### GOVERNMENT LICENSE RIGHTS

This invention was made with government support under Grant No. DE-SC0004993 awarded by the Department of Energy. The government has certain rights in the invention.

### TECHNICAL FIELD

The present disclosure generally relates to electrolysis, and more specifically, to electrocatalysts for electrochemical reactions.

### BACKGROUND

An outstanding challenge in electrochemistry is the development of active, stable catalysts for electrochemical reactions in corrosive environments, such as oxidative reactions in low pH aqueous electrolytes. The conventional solution to this problem involves the use of noble metal oxides, but the scarcity of these materials can limit the global scalability and increase the operating costs of such electrochemical processes.

An important electrochemical reaction that presents a corrosive environment is the chlor-alkali process, which entails the electrochemical oxidation of chloride to Cl₂(g) by the chlorine-evolution reaction (CER) in conjunction with the production of caustic soda (i.e., NaOH) and H₂. The CER is a common, commercially valuable electrochemical reaction, and is practiced at industrial scale globally. The process is performed at industrial scale globally and consumes over 150 TWh of electricity annually. Dimensionally stable anodes, consisting of noble metal oxides of Ir or Ru, are the predominantly used CER anode electrocatalysts. Indeed, a precious metal solid solution of RuO₂ or IrO₂ with TiO₂ is the predominant electrocatalyst for the CER.

The scarcity of Ir and Ru has the potential to constrain industrial use of the chlor-alkali process and limit chlorine use in applications such as water sanitation. Solid solutions of these metal oxides with TiO₂, SnO₂, CoOₓ, or SbOₓ have been explored to decrease the amount of Ir and Ru used in CER catalysts. The resulting RuO₂—TiO₂ anodes exhibit low corrosion rates and are operationally stable for several years. However, Ru is susceptible to the formation of thermodynamically stable species such as soluble Ru chlorides or gaseous Ru oxides, contributing eventually to catalyst degradation.

Known electrocatalysts for the CER that do not contain noble metals include Co₃O₄ and mixed first-row transition metal oxides. But these materials show limited stability under the corrosive conditions required to obtain selectivity for the CER relative to the oxygen-evolution reaction (OER).

Accordingly, there is a need for an improved electrocatalyst that is suitable for use in corrosive reaction environments on an industrial scale.

### SUMMARY

Disclosed herein are stable, active non-precious metal oxide catalysts, such as transition metal antimonates, for electrochemical reactions in harsh media conditions. These improved electrocatalysts are important for addressing several global challenges such as water electrolysis and decentralized water sanitation.

In accordance with certain exemplary embodiments of the inventive catalysts, an electrocatalyst comprises, consists essentially of, or consists of a metal oxide film containing a crystalline transition metal antimonite (TMA). In certain embodiments, the TMA may include NiSb₂Oₓ, CoSb₂Oₓ, or MnSb₂Oₓ, where x may be greater than zero and less than or equal to six. In some embodiments, the metal oxide film may be formed on a conductive material or substrate, for example, a substrate including an antimony-doped tin oxide (ATO) film.

In accordance with other exemplary embodiments, one or more methods are disclosed for manufacturing an electrocatalyst usable for an electrochemical reaction. The methods may comprise, consist essentially of, or consist of: depositing an antimony-doped tin oxide (ATO) film onto a substrate; depositing a metallic film onto the ATO film; and annealing the ATO film and the metallic film to form a metal oxide film containing a crystalline transition metal antimonite (TMA).

The foregoing summary does not define the limits of the appended claims. Other aspects, embodiments, features, and advantages will be or will become apparent to one with skill in the art upon examination of the following figures and detailed description. It is intended that all such additional features, embodiments, aspects, and advantages be included within this description and be protected by the accompanying claims.

### BRIEF DESCRIPTION OF THE FIGURES

It is to be understood that the drawings are solely for purpose of illustration and do not define the limits of the appended claims. Furthermore, the components in the figures are not necessarily to scale. In the figures, like reference numerals designate corresponding parts throughout the different views.

FIGS. 1A-B present exemplary initial electrochemical behavior of NiSb₂Oₓ, CoSb₂Oₓ, MnSb₂Oₓ, and RuTiOₓ in pH=2.0, 4.0 M NaCl(aq) electrolyte, where x is greater than zero and less than or equal to six. In some embodiments, x is six. FIG. 1A presents cyclic voltammetry of NiSb₂Oₓ, CoSb₂Oₓ, MnSb₂Oₓ, and RuTiOₓ at a scan rate of 10 mV s⁻¹. FIG. 1B presents intrinsic overpotential of NiSb₂Oₓ, CoSb₂Oₓ, MnSb₂Oₓ, and RuTiOₓ determined from cyclic voltammetry data at 1 mA cm⁻² of electrochemically active surface area. The vertical black line in FIG. 1A indicates the thermodynamic potential for chlorine evolution in 4.0 M NaCl(aq).

FIGS. 2A-B present additional exemplary electrochemical behavior of MSb₂Oₓ films (where M is Ni, Co or Mn) and of RuTiOₓ. FIG. 2A presents chronopotentiometry of MSb₂Oₓ films and of RuTiOₓ, at j_{geo}=100 mA cm⁻² in 4.0 M NaCl(aq), pH=2.0 electrolyte. FIG. 2B presents cyclic voltammetry of MSb₂Oₓ films and of RuTiOₓ, after the chonopotentiometry stability experiments, at j_{geo}=100 mA cm⁻² in 4.0 M NaCl(aq), pH=2.0 electrolyte. The cyclic voltammetry data shown in FIG. 2B were recorded after operation for 65 hours for NiSb₂Oₓ and 90 hours for MnSb₂Oₓ, CoSb₂Oₓ and RuTiOₓ.

FIG. 3A presents a comparison between overpotential after extended operation obtained from cyclic voltammetry and chronopotentiometry at j_{geo}=100 mA cm⁻² for CoSb₂Oₓ and RuTiOₓ.

FIG. 3B presents intrinsic overpotential, at 1 mA cm⁻² of electrochemically active surface area determined from cyclic voltammetry and impedance measurements, collected at 1 hour intervals in between chronopotentriometry measurements at j_{geo}=100 mA cm⁻², for NiSb₂Oₓ, CoSb₂Oₓ, MnSb₂Oₓ, and RuTiOₓ.

FIGS. 4A-F present X-ray photoelectron spectra of TMAs before and after electrochemical operation: (A) NiSb₂Oₓ Ni 2p spectra, (B) CoSb₂Oₓ Co 2p spectra, (C) MnSb₂Oₓ Mn 2p spectra, and Sb 3d and O 1s spectra of (D) NiSb₂Oₓ, (E) CoSb₂Oₓ, and (F) MnSb₂Oₓ.

FIG. 5 presents x-ray diffraction of as-synthesized NiSb₂Oₓ films on quartz and ATO, and NiSb₂Oₓ films after electrochemical operation in 4.0 M NaCl(aq), pH=2.0 electrolyte at 100 mA cm⁻² for at least 60 hours.

FIG. 6 presents x-ray diffraction of as-synthesized CoSb₂Oₓ films on quartz and ATO, and CoSb₂Oₓ films after electrochemical operation in 4.0 M NaCl(aq), pH=2.0 electrolyte at 100 mA cm⁻² for at least 60 hours.

FIG. 7 presents x-ray diffraction of as-synthesized MnSb₂Oₓ films on quartz and ATO, and MnSb₂Oₓ films after electrochemical operation in 4.0 M NaCl(aq), pH=2.0 electrolyte at 100 mA cm⁻² for at least 60 hours.

FIG. 8 presents x-ray diffraction of as-synthesized RuTiOₓ films on ATO, and RuTiOₓ films after electrochemical operation in 4.0 M NaCl(aq), pH=2.0 electrolyte at 100 mA cm⁻² for at least 60 hours.

FIGS. 9A-B present scanning-electron microscope images of an exemplary NiSb₂Oₓ catalyst: (A) before operation, (B) after at least 60 hour of operation at 100 mA cm⁻² in 4.0 M NaCl(aq), pH=2.0 electrolyte.

FIGS. 10A-B present scanning-electron microscope images of an exemplary CoSb₂Oₓ catalyst: (A) before operation, (B) after at least 60 hour of operation at 100 mA cm⁻² in 4.0 M NaCl(aq), pH=2.0 electrolyte.

FIGS. 11A-B present scanning-electron microscope images of an exemplary MnSb₂Oₓ catalyst: (A) before operation, (B) after at least 60 hours of operation at 100 mA cm⁻² in 4.0 M NaCl(aq), pH=2.0 electrolyte.

FIGS. 12A-B present scanning-electron microscope images of an exemplary RuTiOₓ catalyst: (A) before operation, (B) after at least 60 hours of operation at 100 mA cm⁻² in 4.0 M NaCl(aq), pH=2.0 electrolyte.

FIGS. 13A-D present roughness factors determined from impedance data collected at 1 hour intervals between chronopotentiomery stability tests at 100 mA cm⁻² for (A) NiSb₂Oₓ, (B) CoSb₂Oₓ, (C) MnSb₂Oₓ, and (D) RuTiOₓ.

FIGS. 14A-C present experimental results showing the amounts of Ni, Mn, or Co and Sb dissolved from MSb₂Oₓ (where M is Ni, Mn, or Co) electrodes operated at 100 mA cm⁻² in 4.0 M NaCl, pH=2.0 electrolyte for at least 50 hours: (A) NiSb₂Oₓ, (B) CoSb₂Oₓ, (C) MnSb₂Oₓ.

FIGS. 15A-B present (A) chronopotentiometry of ATO and SbOₓ at 100 mA cm⁻², and (B) chronopotentiometry of NiOₓ, CoOₓ, and MnOₓ at 100 mA cm⁻².

FIGS. 16A-D present Tafel plots from 10⁻² to 10² mA cm⁻² before and after 50 hour of operation at 100 mA cm⁻² for (A) NiSb₂Oₓ, (B) CoSb₂Oₓ, (C) MnSb₂Oₓ, and (D) RuTiOₓ. The current-voltage data was collected from cyclic voltammograms.

FIGS. 17A-D present cyclic voltammograms collected under chlorine evolution reaction (CER) conditions [4.0 M NaCl(aq), pH=2.0] and oxygen evolution reaction (OER) conditions [pH=2.0 H₂SO₄(aq)] for (A) NiSb₂Oₓ, (B) CoSb₂Oₓ, (C) MnSb₂Oₓ, and (D) RuTiOₓ.

### DETAILED DESCRIPTION

The following detailed description, which references to and incorporates the drawings, describes and illustrates one or more examples of electrocatalysts and methods of manufacturing and using those electrocatalysts for electrochemical reactions, such as the chlorine evolution reaction (CER). These examples, offered not to limit but only to exemplify and teach embodiments of the inventive electrocatalysts and electrodes incorporating said electrocatalysts, are shown and described in sufficient detail to enable those skilled in the art to practice what is claimed. Thus, where appropriate to avoid obscuring the invention, the description may omit certain information known to those of skill in the art. The disclosures herein are examples that should not be read to unduly limit the scope of any patent claims that may eventual be granted based on this application.

The word “exemplary” is used throughout this application to mean “serving as an example, instance, or illustration.” Any system, method, device, technique, feature or the like described herein as “exemplary” is not necessarily to be construed as preferred or advantageous over other features.

As used in this specification and the appended claims, the singular forms “a,” “an,” and “the” include plural referents unless the content clearly dictates otherwise.

Although any methods and materials similar or equivalent to those described herein can be used in the practice or testing of the invention(s), specific examples of appropriate materials and methods are described herein.

Also, the use of “or” means “and/or” unless stated otherwise. Similarly, “comprise,” “comprises,” “comprising” “include,” “includes,” and “including” are interchangeable and not intended to be limiting.

It is to be further understood that where descriptions of various embodiments use the term “comprising,” those skilled in the art would understand that in some specific instances, an embodiment can be alternatively described using language “consisting essentially of” or “consisting of.”

A “conductive material” as used herein refers to a material that allows the flow of an electrical current in one or more directions. Materials made of metal are common electrical conductors. Electrical current is generated by the flow of negatively charged electrons, positively charged holes, and positive or negative ions in some cases. Examples of conductive materials, include but are not limited to, metals, alloys, metal containing compounds, graphite, and conductive polymers. Examples of good conducting metals include but are not limited to, silver, copper, gold, aluminum, molybdenum, zinc, lithium, tungsten, brass, nickel, iron, palladium, platinum, and tin.

An “electrocatalyst” as used herein refers to a catalyst that participates in an electrochemical reaction, and which modifies or increases the rate of the electrochemical reaction without being substantially consumed in the process. An electrocatalyst can be heterogeneous such as a metal oxide surface, or homogeneous like a coordination complex. The electrocatalyst assists in transferring electrons between the electrode and reactants, and/or facilitates an intermediate chemical transformation described by an overall half-reaction.

An “electrochemical reaction” as used herein refers to a process either caused or accompanied by the passage of an electrons or an electric current and involving in most cases the transfer of electrons between two substances. The energy of an electric current can then be used to bring about many chemical reactions that do not occur spontaneously. Examples of “electrochemical reactions” include the chlorine evolution reaction, the oxygen evolution reaction, the hydrogen evolution reaction, the carbon dioxide reduction reaction, the electrochemical water splitting reaction, the nitrogen reduction reaction, and the oxygen reduction reaction.

Electrocatalysts are used both to speed up electrode reactions and to enable them to occur close to their thermodynamically predicted potentials. An electrocatalyst is said to reduce the overvoltage for the electrode reaction. An example is the water electrolysis cell; electrocatalysts are important here to lower the minimum voltage necessary for electrolysis to occur, and to keep it low as the rate of electrolysis at the electrodes is increased—this may permit higher efficiency of operation.

Crystalline transition metal antimonates (TMAs) are active and stable electrocatalysts for water oxidation in acidic electrolytes. Moreover, Pourbaix diagrams indicate that crystalline TMAs such as NiSb₂O₆, CoSb₂O₆, and MnSb₂O₆ should be stable under acidic conditions as well as in the presence of Cl₂(g).

Accordingly, disclosed herein are particular exemplary embodiments of electrocatalysts that include TMAs. The disclosed embodiments also include methods of manufacturing such electrocatalysts, which methods involve the synthesis of metal oxide films containing crystalline MSb₂O₆ (M=Ni, Co, Mn). The electrochemical activity and stability of these materials for the CER in acidic NaCl(aq) are disclosed, too. Also disclosed is the electrochemical stability at or about 100 mA cm⁻² of anodic current density, due to the relevance of this current density for the commercially-practiced chlor-alkali process. The structural, chemical, and dissolution behaviors of crystalline MSb₂O₆ for the CER, as evaluated by scanning-electron microscopy, x-ray photoelectron spectroscopy, and inductively coupled plasma mass spectrometry, are further disclosed herein.

In certain embodiments, films of NiSb₂, CoSb₂, and MnSb₂ were prepared by co-sputtering Sb and M (M=Ni, Co, or Mn) onto conductive antimony-doped tin oxide (ATO) substrates.

Exemplary materials comprised only of non-precious metal elements, for example, crystalline transition-metal antimonates (TMAs) such as NiSb₂Oₓ, CoSb₂Oₓ, and MnSb₂Oₓ, are active, stable catalysts for the electrochemical oxidation of chloride to chlorine under conditions relevant to the commercial chlor-alkali process. These materials are incorporated into particular embodiments of the disclosed electrocatalysts, as described herein. Specifically, in certain embodiments, a CoSb₂Oₓ catalyst exhibited a galvanostatic overpotential, η_{g}, <545 mV at 100 mA cm⁻² of Cl₂(g) production from aqueous pH=2, 4.0 M NaCl(aq) after 90 hours of operation. As described herein, examination of the bulk and surface of the disclosed electrocatalysts and the composition of the electrolyte before and after electrolysis indicated minimal changes in the surface structure and intrinsic activity of CoSb₂Oₓ as a result of Cl₂(g) evolution under these conditions.

The disclosure further provides for one or more electrodes which comprises one or more electrocatalysts disclosed herein. In a particular embodiment, an anode comprises one or more electrocatalysts disclosed herein. In an alternate embodiment, a cathode comprises one or more electrocatalysts disclosed herein. In a further alternate embodiment, a cathode and an anode comprises one or more electrocatalysts disclosed herein. In a further embodiment, an electrode which comprises one or more electrocatalysts disclosed herein is used in an electrochemical reaction. Examples of electrochemical reactions, include but are not limited to, the chlorine evolution reaction.

The following examples are intended to illustrate but not limit the disclosure. While they are typical of those that might be used, other procedures and/or materials known to those skilled in the art may alternatively be used.

### EXAMPLES

Chemicals: All chemicals were used as received, including antimony(III) chloride (SbCl₃, available from Alfa Aesar, ACS, 99.0% min), tin(IV) chloride hydrate (SnCl₄.xH₂O, Alfa Aesar, 98%), sodium chloride (NaCl, Macron Chemicals, ACS grade), 1.0 M hydrochloric acid (1.0 M HCl(aq), Fluka Analytical), multielement standard solution 1 for ICP (Sigma Aldrich, TraceCERT), sulfuric acid (H₂SO₄(aq), Fischer Scientific, TraceMetal grade, 93-98%), sodium hydroxide (NaOH, Macron Chemicals, ACS grade), antimony standard for ICP (Sigma Aldrich, TraceCER), potassium chloride (KCl, Macron Chemicals, ACS grade), and gallium-indium eutectic (Alfa Aesar, 99.99%). Deionized water with a resistivity of 18.2 MΩ-cm was obtained from a Millipore deionized water system.

Method Electrocatalyst Electrode Manufacture:

To produce electrode samples, a spray pyrolysis procedure was used to deposit conductive films of antimony-doped tin oxide (ATO). The process consisted of spraying a 0.24 M SnCl₄ solution in ethanol doped with 3 mol % SbCl₂ onto a quartz microscope slide heated at 550° C. on a hot plate. The thickness of the ATO film was adjusted by controlling the duration of the spray. ATO films with a sheet resistance of 5-10Ω sq⁻¹, as determined from four-point probe measurements, were used for subsequent experiments.

Metallic films of Ni, Co, Mn, Sb, NiSb₂, CoSb₂, and MnSb₂ were deposited onto the ATO substrates with an AJA Orion sputtering system, respectively, to obtain the sample electrocatalysts. The ATO substrates were partially covered with Kapton tape to prevent complete coverage of the ATO with the catalyst films, to form a direct contact between the ATO and the working electrode wire. The metallic films were co-sputtered from four metallic targets in an Ar plasma: Antimony (ACI Alloys, 99.95%), Nickel (ACI Alloys, 99.95%), Cobalt (ACI Alloys, 99.95%), and Manganese (ACI Alloys 99.95%). The chamber pressure was <10⁻⁷ Torr prior to the depositions. A chamber pressure of 5 mTorr was sustained during the depositions with an Ar flow rate of 20 sccm. The samples were not intentionally heated during the deposition process. The power applied to the metal targets was varied to obtain similar transition metal loadings and a stoichiometry close to 2:1 Sb:M in MSb_{X} samples. The actual stoichiometry and loading of Ni, Co, Mn, and Sb was determined by dissolving in 1.0 M H₂SO₄(aq) films deposited on glass, and then using the concentration of the metals as determined by ICP-MS, the areas of the samples dissolved, and the amount of H₂SO₄(aq) used during the dissolution to obtain the total loading.

After the metal films were deposited on ATO, the films were annealed in a muffle furnace (Thermolyne F48020-80) to form the crystalline oxides. To obtain MSb₂Oₓ films, the Ni, Co, and Mn metal/Sb films were annealed at 750° C. in air. In some embodiments, the temperature was increased to 750° C. at a ramp rate of 10° C. min⁻¹, was held at 750° C. for 6 hours, and then allowed to return to room temperature without active cooling. RuTiOₓ films with the same molar loading (˜1.5 μmol cm⁻²) as the MSb₂Oₓ films were prepared by drop casting 4 μL cm⁻² of a 0.11 M RuCl₃ and 0.26 M TiCl₄ solution in ethanol onto ATO, followed by drying on a hot plate at 400° C. The RuTiOₓ was annealed at 500° C. for 1 hour in a muffle furnace. The samples were cleaved into pieces that had exposed ATO regions, and In—Ga eutectic was scribed on the ATO. The electrode support consisted of a tinned Cu wire that was threaded through a glass tube. The Cu wire was coiled and bonded to the ATO substrate by use of Ag paint (SPI, Inc). The contact was allowed to dry for at least 2 hours at room temperature or for 15 min at 85° C. in an oven. Hysol 9460 epoxy was used to insulate the Cu, ATO, and In—Ga from the electrolyte and to define the geometric electrode area. The epoxy was allowed to cure for >12 hours at room temperature or for 2 hours at 85° C. in an oven. The electrode area and a calibration ruler was imaged with an optical scanner (Epson Perfection V360), and the electrode area was quantified with ImageJ software. Electrode areas were between 1 and 40 mm² unless otherwise specified.

The catalyst loading and stoichiometry of the sputtered metallic films were determined by dissolving the films in 1.0 M H₂SO₄(aq) and measuring the amount of dissolved ions by inductively coupled plasma mass spectrometry (ICP-MS).

Inductively-coupled plasma mass spectrometry: An Agilent 8000 Triple Quadrupole Inductively Coupled Plasma Mass Spectrometer (ICP-MS) system was used to determine the concentration of various ions in aqueous samples. Calibration solutions were prepared by diluting antimony and multielement standard solutions (Sigma Aldrich) with 18.2 MΩ cm resistivity water. The concentration of various ions was determined from a linear fit of the counts per second of each standard solution versus the known concentration. The mass loading of the TMAs was determined by depositing the MSb₂ (M=Ni, Co, Mn) layers on glass slides that were then cut into ˜1 cm⁻² pieces. The projected area of the pieces was determined with a calibrated optical scanner and ImageJ software. The MSb₂ layers were dissolved in 10 mL of 1.0 M H₂SO₄(aq) for >100 hours, and samples from these solutions were diluted with water and analyzed with ICP-MS. The loading of the catalyst layer was determined using the concentration of M and Sb, the volume of 1.0 M H₂SO₄(aq), and the projected area of the MSb₂ layers. The dissolution of species from TMAs films under chlorine evolution conditions was determined by collecting 40 μL samples of electrolyte from a cell operating at 100 mA cm⁻² with an initial 5 mL volume of 4.0 M NaCl(aq), pH=2 electrolyte in the anode compartment, and diluting these samples to 5 mL with 18.2 MΩ cm resistivity water. The amount of M and Sb lost was determined from the concentration, volume of the cell, and electrode area. The amount of M and Sb removed from the cell after each sample was collected was taken into account when determining the amount of metals lost over time during chronopotentiometry measurements.

The loading of transition metal was 375-483 nmol cm⁻² whereas the Sb loading was 709-820 nmol cm⁻², indicating a bulk M:Sb atomic ratio of ˜1:2 (Table 1).

Table 1 presents catalyst loading of exemplary MSb₂Oₓ (M=Ni, Co, or Mn) films determined from ICP-MS measurements of MSb₂ films dissolved in 1.0 M H₂SO₄(aq).

| | M Loading | Sb Loading |
|---|---|---|
| Catalyst | (nmol cm⁻²) | (nmol cm⁻²) |
| NiSb₂Oₓ | 483 ± 3 | 763 ± 5 |
| CoSb₂Oₓ | 375 ± 4 | 820 ± 5 |
| MnSb₂Oₓ | 417 ± 9 | 709 ± 8 |

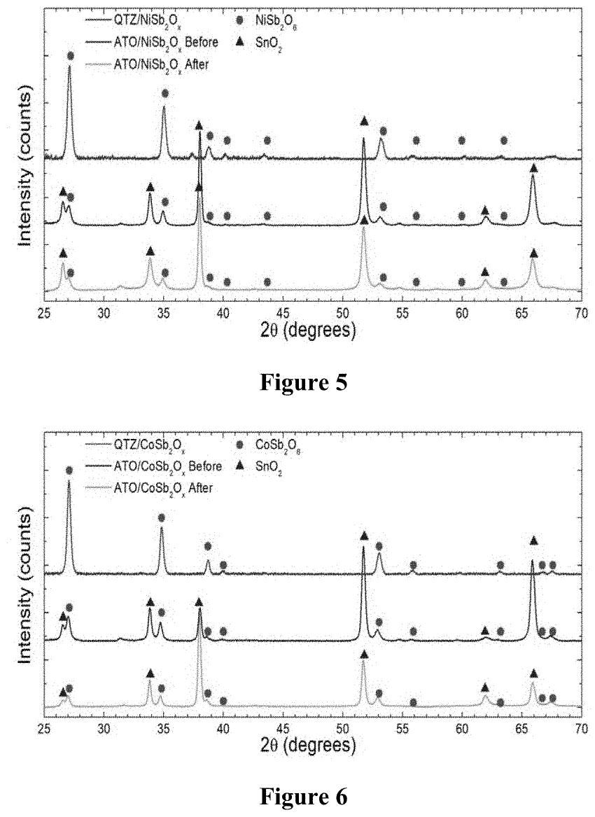

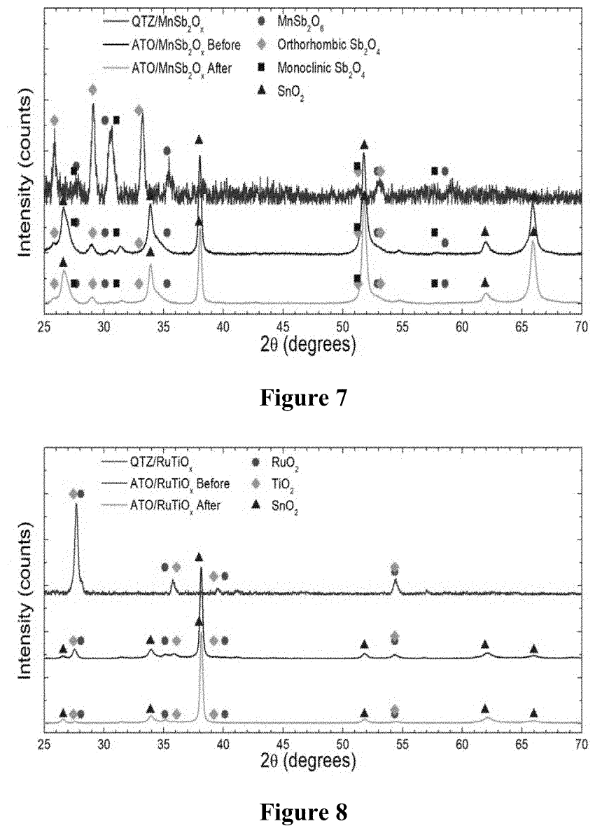

X-ray diffraction (XRD) data indicated that the NiSb₂Oₓ and CoSb₂Oₓ films both contained the tri-rutile MSb₂O₆ structure (FIGS. 5 and 6). MnSb₂Oₓ films contained MnSb₂O₆, orthorhombic Sb₂O₄, and monoclinic Sb₂O₄ (FIG. 7). RuTiOₓ films deposited on ATO and annealed at 500° C. exhibited diffraction peaks consistent with a solid solution of rutile-type RuO₂ and TiO₂ (FIG. 8).

Materials Characterization: X-ray diffraction (XRD) data were collected with a Bruker D8 Discover instrument. The Cu Kα (1.54 Å) x-ray beam was generated with a tube current of 1000 μA and a tube voltage of 50 kV, and was detected with a Vantec-500 2-dimensional detector. The incident beam was collimated with a 0.5 mm diameter mono-capillary collimator. A calibrated visible laser was used to align the sample with the x-ray beam. XRD data were collected in coupled θ-2θ mode, with four scans collected every 20° from a 2θ theta range of 20°-80°. The x-ray radiation was collected for 1 hour for each scan, corresponding to 4 hours per sample. The 2-dimensional signal was integrated to obtain a 1-dimensional scan with an angular resolution of 0.01° 2θ. The x-ray diffraction peaks were analyzed using Bruker EVA software with reference patterns of SnO₂ for the ATO substrate, in addition to reference patterns for monoclinic Sb₂O₄, orthorhombic Sb₂O₄, NiSb₂O₆, CoSb₂O₆, MnSb₂O₆, RuO₂ and TiO₂ obtained from the Crystallography Open Database or literature. Scanning-electron microscopy (SEM) images were collected using immersion mode with an accelerating voltage of 10 kV on a Nova nanoSEM 450 (FEI) instrument.

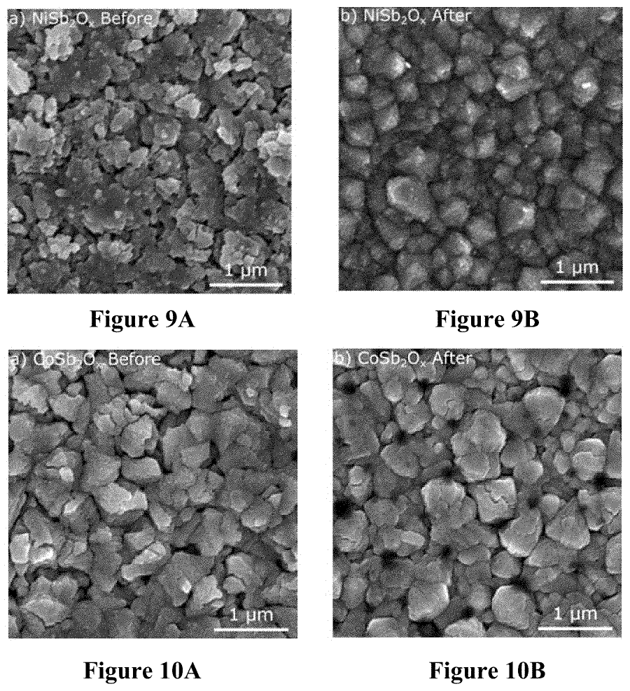

Scanning-electron microscopy (SEM) images of the catalyst films indicated that the morphology was different for each film (FIGS. 9-12).

The electrochemical behavior of the TMAs was evaluated by cyclic voltammetry (CV), impedance spectroscopy, and chronopotentiometry in 4.0 M NaCl(aq) that was adjusted to pH=2 with 1.0 M HCl(aq). For comparison to the behavior of the TMA's, dimensionally stable RuTiOₓ anodes were also evaluated.

Electrochemical Testing:

NaCl was used to make 4.0 M aqueous solutions, and 1 M HCl(aq) was used to adjust the pH to 2 as measured by a pH probe. A saturated calomel electrode (SCE) was calibrated with a standard hydrogen electrode (SHE). The SHE consisted of a platinum disk (CH Instruments) submerged in a H₂ saturated 1.0 M sulfuric acid electrolyte, with H₂(g) bubbled underneath the Pt disk to ensure saturation. The potential of the SCE was 0.244 V vs. SHE. Electrochemical measurements were collected in a two-compartment cell with the compartments separated using a Nafion N424 membrane. The cathode compartment was filled with 0.1 M NaOH(aq), and the anode compartment was filled with 4.0 M NaCl(aq) adjusted to pH=2 with HCl(aq). The working and reference electrodes were placed in the anode compartment, and the counter electrode was placed in the cathode compartment. The working, reference, and counter electrodes consisted of the sample, an SCE, and a carbon rod or Ni wire, respectively. The anode compartment was saturated with Cl₂(aq) by applying ˜10 V for at least 30 minutes between the counter electrode and a second working electrode that consisted of a graphite rod. Cyclic voltammograms were collected at a scan rate of 10 mV s⁻¹ unless otherwise specified. Electrochemical data were collected using a digital potentiostat (SP-200, Bio-Logic). The thermodynamic potential for chlorine evolution was calculated to be 1.33 V vs. SHE in 4.0 M NaCl(aq).

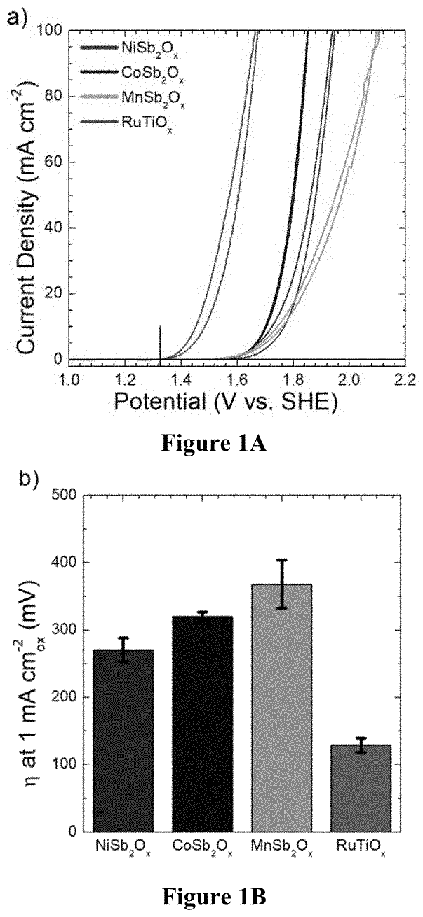

FIG. 1a shows typical cyclic voltammograms for NiSb₂Oₓ, CoSb₂Oₓ, MnSb₂Oₓ, and RuTiOₓ at a scan rate of 10 mV s⁻¹ in the potential range of 1.0 to 2.1 V versus a standard hydrogen electrode (SHE). The overpotential (ηₑᵥ) of the electrocatalyst films was determined at geometric current densities, j_{geo} of 110 and 100 mA cm⁻², respectively, from the cyclic voltammetry data (Table 2).

Table 2 presents overpotentials (ηₑᵥ) of exemplary MSb₂Oₓ films and RuTiOₓ film determined from cyclic voltammetry data prior to galvanostatic operation at geometric current densities of 1, 10, and 100 mA cm⁻² in pH=2.0, 4.0 M NaCl(aq). Roughness factors (RF) were determined from impedance data at 1.660 V vs. SHE.

TABLE 2

| | η_{cv} at 1 mA | η_{cv} at 10 mA | η_{cv} at 100 mA | |
|---|---|---|---|---|
| | cm⁻² | cm⁻² | cm⁻² | |
| Catalyst | (mV) | (mV) | (mV) | RF |
| NiSb₂Oₓ | 270 ± 17 | 371 ± 39 | 565 ± 45 | 1.1 ± 0.1 |
| CoSb₂Oₓ | 237 ± 33 | 345 ± 23 | 502 ± 16 | 6.6 ± 2.5 |
| MnSb₂Oₓ | 264 ± 4 | 391 ± 27 | 674 ± 88 | 9.0 ± 5.2 |
| RuTiOₓ | 39 ± 17 | 129 ± 29 | 328 ± 53 | 8.8 ± 3.9 |

The roughness factor (RF) of the TMAs was determined by comparing the electrochemically active surface area (ECSA) of bare ATO substrates and TMAs, as determined from impedance measurements. Impedance measurements were collected in 4.0 M NaCl(aq) adjusted to pH=2 with the electrolyte additionally saturated with Cl₂(aq). ATO substrates prepared by a spray deposition method have previously been determined from atomic force microscopy measurements to have a RF=1.32. Electrodes were held at 1.660 V vs. SHE for 15 seconds prior to impedance measurements, which were collected at the same potential with a frequency range of 20 Hz-20 kHz, with a sinusoidal wave amplitude of 10 mV. The impedance data were fit with a circuit model consisting of a resistor in series with a parallel components consisting of a constant phase element and another resistor. The capacitance was obtained by using a formula previously reported for the analysis of this circuit. The geometric-area normalized capacitance of ATO was 14.4±1.6 μF cm⁻², which corresponds to an electrochemical surface area normalized capacitance of 11±1 μF cmₒₓ⁻². The roughness factor of the TMAs was determined by diving the geometric-area normalized capacitance of the TMAs by the electrochemical surface area normalized capacitance of ATO (11 μF cmₒₓ⁻²).

The CVs and overpotential measurements both indicated that RuTiOₓ exhibited the highest initial activity, with η_{cv}˜129 mV at j_{geo}=10 mA cm⁻². For comparison, under nominally identical test conditions MSb₂Oₓ films exhibited η_{cv}˜345-391 mV at j_{geo}=10 mA cm⁻². Impedance measurements yielded electrode resistances in the range of 20-200Ω for NiSb₂Oₓ, CoSb₂Oₓ, MnSb₂Oₓ, and RuTiOₓ films, hence compensation of 90% of the electrode resistance for electrodes with a geometric area of 0.01-0.1 cm⁻² resulted in <30 mV of voltage compensation at j_{geo}=10 mA cm⁻² for most of the catalysts disclosed herein.

Measurements of the electrochemically active surface area (ECSA) by impedance spectroscopy of the TMAs indicated that NiSb₂Oₓ, CoSb₂Oₓ, MnSb₂Oₓ, and RuTiOₓ films initially had roughness factors of 1.1±0.1, 6.6±2.5, 9.0±5.2, and 8.8±3.9, respectively (Table 2).

The initial intrinsic activity of the electrocatalyst films was evaluated by determining the overpotential required to obtain 1 mA per cm⁻² of ECSA, as shown in FIG. 1B. The overpotential at 1 mA cm⁻² of ECSA, which corresponds to a geometric current density of 1-15 mA cm⁻² for roughness factors of 1-15 as observed herein, is referred to as the intrinsic overpotential (ηᵢ). The NiSb₂Oₓ, CoSb₂Oₓ, MnSb₂Oₓ, and RuTiOₓ films exhibited a 1 mA cm⁻² initial intrinsic overpotential of 271±18, 321±6, 368±36, and 129±10 mV, respectively (FIG. 1B, Table 3). The initial ηᵢ measurements thus indicated that RuTiOₓ was the most active electrocatalyst at this current density, followed by NiSb₂Oₓ, CoSb₂Oₓ, and MnSb₂Oₓ.

Table 3 presents intrinsic overpotential (ηᵢ) at 1.0 mA cm⁻² of ECSA and Tafel slope (b) of MSb₂Oₓ films and RuTiOₓ prior to and after 50 hour of galvanostatic operation at 100 mA cm⁻². The Tafel slope was determined from a linear fit of a plot of η vs. log₁₀(J) between geometric current densities of 0.2 to 2.0 mA cm⁻². All Tafel slopes had an R-squared value greater than 0.99.

TABLE 3

| | ηᵢ at 0 h | ηᵢ at 50 h | b at 0 h | b at 50 h |
|---|---|---|---|---|
| Catalyst | (mV) | (mV) | (mV dec⁻¹) | (mV dec⁻¹) |
| NiSb₂Oₓ | 271 ± 18 | 580 | 94 | 131 |
| CoSb₂Oₓ | 321 ± 6 | 374 | 73 | 74 |
| MnSb₂Oₓ | 368 ± 36 | 458 | 110 | 110 |
| RuTiOₓ | 129 ± 10 | 232 | 69 | 134 |

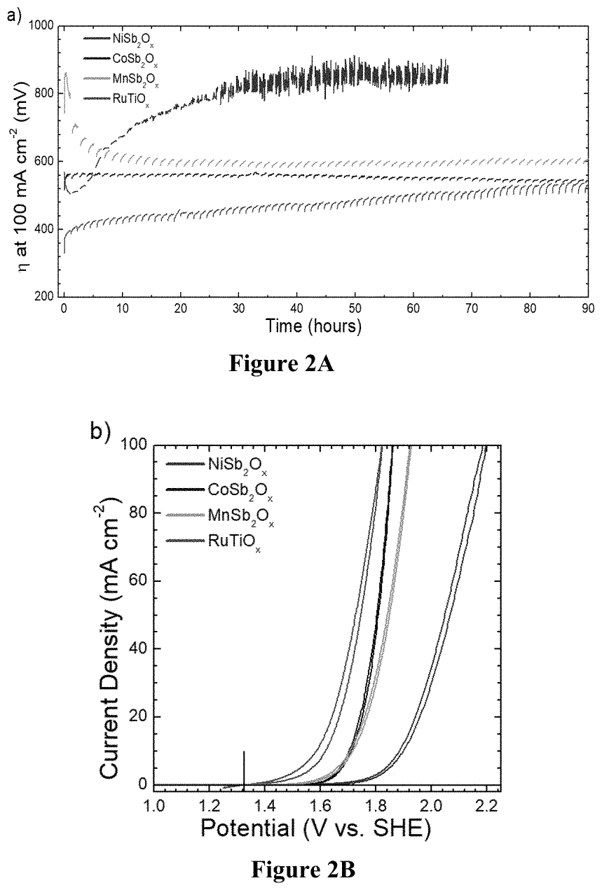

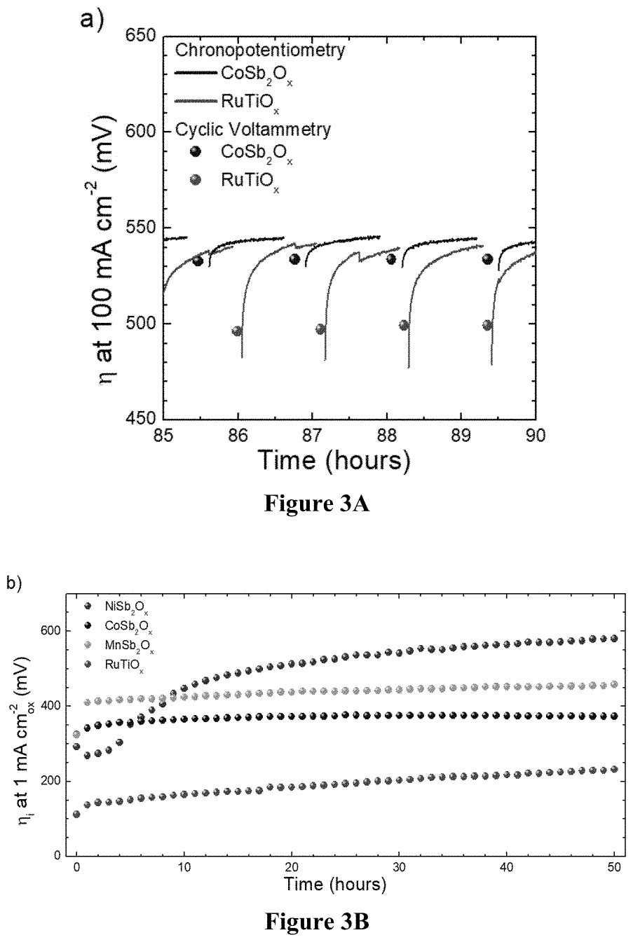

FIG. 2A shows the electrochemical stability of the TMAs under galvanostatic control at j_{geo}=100 mA cm⁻². Cyclic voltammetry data were obtained before at 1 hour intervals after the chronopotentiometry data were collected (FIG. 2B). The overpotential increased slowly during the 1 hour of chronopotentiometry with an abrupt decrease after cyclic voltammograms and impedance data were collected. High frequency transient increases in overpotential were also observed due to partial blockage of the catalyst film as a result of Cl₂(g) evolution. FIG. 3A shows a comparison between the overpotential obtained from cyclic voltammetry and chronopotentiometry at 100 mA cm⁻² after 85 hours of operation for CoSb₂Oₓ and RuTiOₓ. In general, the overpotential observed during extended chronopotentiometry was 10-50 mV larger than the overpotential determined by cyclic voltammetry.

The measured electrochemical testing and performance of samples of each disclosed metal oxide catalyst is discussed below, in turn. Results are also presented for TMA-free electrodes, as controls.

NiSb₂Oₓ Catalyst:

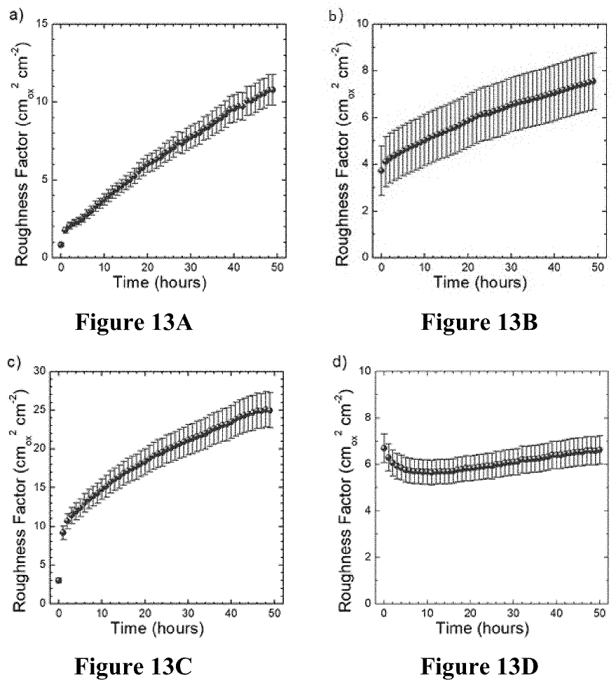

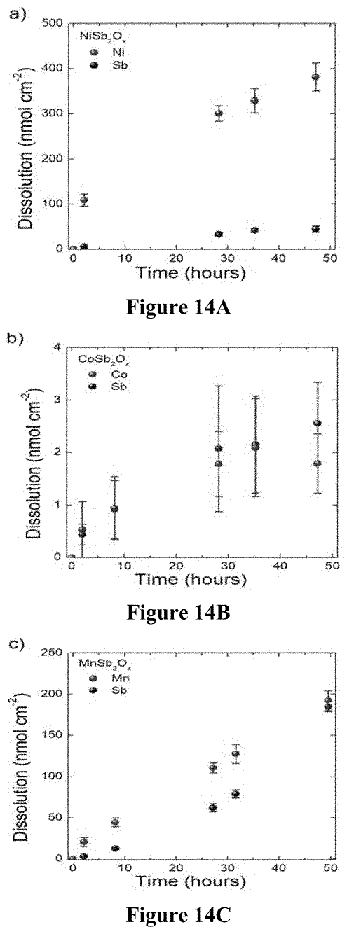

For NiSb₂Oₓ, the overpotential at j_{geo}=100 mA cm⁻² under galvanostatic control averaged 543±15 mV during the first 30 minutes of operation, after which η_{g} decreased to a minimum value of 511±2 mV for 1-2 hours of operation (FIG. 2A). Then η_{g} gradually increased and stabilized after 40 hours, with an average value of 853±22 mV from 50-65 hours of operation at j_{geo}=100 mA cm⁻² (FIG. 2A). The fluctuation in overpotential observed for NiSb₂Oₓ after 30 hours was due to a periodic decrease in the overpotential every 5-10 minutes associated with bubble detachment. Impedance measurements collected after 1 hour intervals of galvanostatic control indicated substantial changes in the capacitance and series resistance of the NiSb₂Oₓ-coated electrode. The series resistance of the NiSb₂Oₓ catalyst increased from 101Ω to 165Ω over 50 hours of chronopotentiometry at j_{geo}=100 mA cm⁻². The increase in series resistance accounted for ˜88 mV of the observed increase in overpotential for this film. Impedance data collected at 1 hour intervals indicated that NiSb₂Oₓ exhibited an increase in ECSA from ˜1 to ˜11 after 50 hours of chronopotentiometry (FIG. 13A).

The appearance of Ni and Sb in the electrolyte was measured using ICP-MS (FIG. 14A). After 50 hours of operation, 380 nmol cm⁻² of Ni and 45 nmol cm⁻² of Sb were present in the electrolyte. The detected concentration corresponded to 79±6% of the Ni and 6±1% of the Sb in the original catalyst film, indicating substantial loss of the catalyst layer. XRD of the electrode after electrochemical operation for 50 hours indicated that crystalline NiSb₂O₆ remained in the catalyst film (FIG. 5). SEM images indicated a loss of catalyst loading from the surface, while also indicating that the substrate remained coated with a conformal layer of catalyst (FIG. 9).

CoSb₂Oₓ Catalyst: At j_{geo}=100 mA cm⁻², the galvanostatic overpotential of CoSb₂Oₓ initially increased from ˜520 to ˜560 mV during the first 1 hour of operation, and subsequently remained at ˜545 mV after 90 hours (FIG. 2A). FIG. 3A shows the comparison between the overpotential obtained from cyclic voltammetry and chronopotentiometry between 85-90 hours of operation. The overpotential from cyclic voltammetry was ˜533 mV, which was ˜12 mV lower than the galvanostatic overpotential of ˜545 mV measured immediately preceding the cyclic voltammetry scans. Impedance measurements collected after the 1 hour galvanostatic intervals indicated minor changes in the ECSA (FIG. 13B). The series resistance of CoSb₂Oₓ remained in the range of 30-34Ω during the chronopotentiometric experiment, accounting for <10 mV in the observed variation of the overpotential. The roughness factor increased from ˜4 to ˜8 after 50 hours of operation. Less than 2 nmol cm⁻² of Co and 3 nmol cm⁻² of Sb dissolved into the electrolyte after 50 hours of operation (FIG. 14B), corresponding to a loss of ˜0.6 nm and ˜0.3 nm of catalyst or 0.5±0.1% Co and 0.3±0.1% Sb, respectively. After electrochemical operation for 50 hours, XRD data indicated that crystalline CoSb₂O₆ remained on the CoSb₂Oₓ catalyst film (FIG. 6). SEM images indicated that the morphology of CoSb₂Oₓ films tested for 50 hours at j_{geo}=100 mA cm⁻² was similar to the morphology of as-synthesized films (FIG. 10).

MnSb₂Oₓ Catalyst:

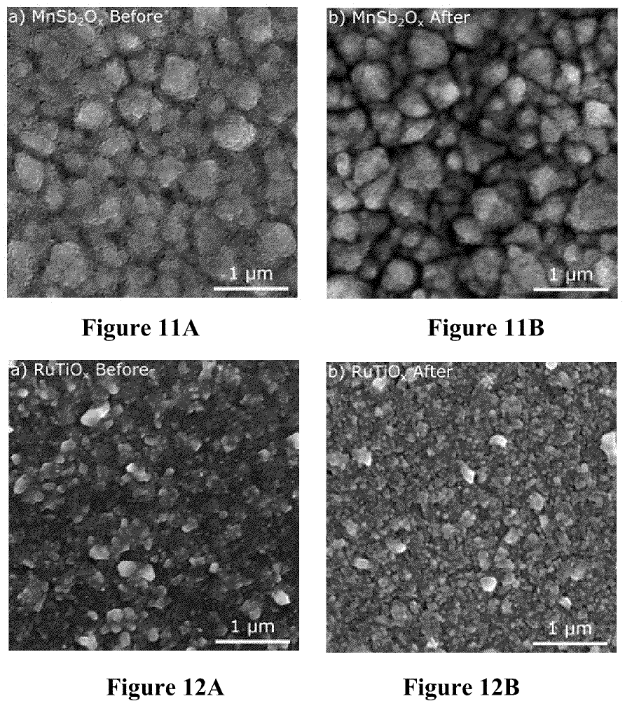

Over the first 0.3 hours of operation at j_{geo}=100 mA cm⁻², the galvanostatic overpotential of MnSb₂Oₓ initially increased to ˜860 mV, followed by a gradual decrease to ˜605 mV over 20 hours, followed by an average overpotential of 595±6 mV from 20 to 90 hours of operation (FIG. 2A). The series resistance of the MnSb₂Oₓ was between 144-168Ω during the stability test, accounting for ˜40 mV in the observed variability in overpotential. The roughness factor of the MnSb₂Oₓ film gradually increased from ˜3 to ˜25 over 50 hours of chronopotentiometry (FIG. 13C). ICP-MS of the electrolyte indicated that 192 nmol cm⁻² and 185 nmol cm⁻² of Mn and Sb dissolved in the electrolyte, corresponding to 46±3% of Mn and 26±1% of Sb in the catalyst film (FIG. 14C). After electrochemical operation, XRD confirmed that crystalline MnSb₂O₆, monoclinic Sb₂O₄, and orthorhombic Sb₂O₄ remained in the catalyst film (FIG. 7). After electrochemical operation, SEM images showed a loss of catalyst loading as well as an increase in film porosity (FIG. 11).

RuTiOₓ Catalyst:

FIG. 2A shows chronopotentiometry data for RuTiOₓ at j_{geo}=100 mA cm⁻². The initial galvanostatic overpotential was η_{g}˜330 mV and η_{g} increased to ˜540 mV after 90 hours of operation. FIG. 3A shows the comparison between the overpotential obtained from cyclic voltammetry and chronopotentiometry between 85-90 hours of operation. The overpotential from cyclic voltammetry was ˜497 mV, whereas the overpotential was ˜540 mV from chronopotentiometry immediately preceding the cyclic voltammetry scans. The roughness factor of RuTiOₓ remained essentially constant throughout the chronopotentiometry experiment (FIG. 13D). The series resistance of RuTiOₓ electrodes was 17-18Ω and remained within this range for the duration of the stability test. XRD indicated that RuO₂ and TiO₂ remained in the catalyst film after electrochemical testing (FIG. 8). SEM images indicated an increase in the porosity of the RuTiOₓ films after electrochemical operation (FIG. 12).

TMA-Free Electrodes:

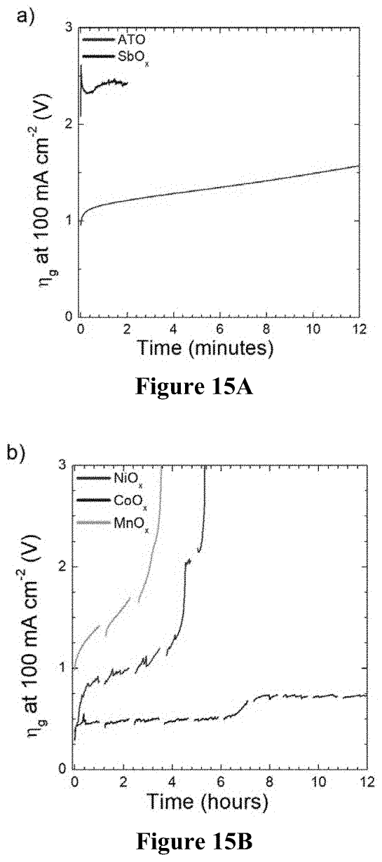

To serve as controls, SbOₓ on ATO and ATO electrodes were prepared without TMA electrocatalyst coatings. These electrodes exhibited η_{g}>1,000 mV at j_{geo}=100 mA cm⁻² under galvanostatic control. The electrochemical stability of the transition metal oxides NiOₓ, CoOₓ, and MnOₓ was determined using electrocatalyst films that were prepared by the same procedure and transition-metal loading as the MSb₂Oₓ films, except that Sb was not co-sputtered during the metal deposition. Electrodes consisting of NiOₓ or MnOₓ were unstable for chlorine evolution at j_{geo}=100 mA cm⁻² under galvanostatic control (FIG. 15B). CoOₓ electrodes exhibited η_{g}˜470 mV at j_{geo}=100 mA cm⁻² under galvanostatic control during the first 6 hours of operation, but the overpotential increased to η_{g}>720 mV after 8 hours of operation (FIG. 15B).

Intrinsic Activity of the Electrocatalysts:

The intrinsic activity of the electrocatalyst films was obtained by calculating the intrinsic overpotential after 1 hour intervals of galvanostatic control. After each 1 hour interval of chronopotentiometry at j_{geo}=100 mA cm⁻², cyclic voltammetry and impedance measurements were collected to determine the ECSA, η_{cv}, series resistance, and ηᵢ, of the catalyst films. Each intrinsic overpotential was corrected at 90% of the series resistance determined for each time interval. FIG. 3b shows the values of ηᵢ at 1 mA cm⁻² of ECSA for NiSb₂Oₓ, CoSb₂Oₓ, MnSb₂Oₓ, and RuTiOₓ obtained from these measurements. In general, the qualitative changes in both the overpotential (FIG. 2) and the intrinsic overpotential (FIG. 3B) were similar during operation for most of the electrocatalyst films. FIG. 3B shows the intrinsic overpotential for representative electrodes, whereas Table 3 shows the average and standard deviation for the electrocatalysts studied herein. FIG. 3B shows that NiSb₂Oₓ exhibited an ηᵢ of 293 mV initially, that decreased to a minimum value of 269 mV after 1 hour of operation and subsequently increased gradually, to 580 mV after 50 hours of operation. CoSb₂Oₓ initially exhibited an ηᵢ of 325 mV, that gradually increased to 373 mV over 20 hours, followed by a stable ηᵢ of 373-376 mV from 20 to 50 hours of operation. MnSb₂Oₓ initially exhibited ηᵢ=324 mV, that then increased to 410 mV after 1 hour of operation, followed by a gradual increase to ηᵢ=458 mV after 50 hours of operation. RuTiOₓ exhibited an initial ηᵢ of 112 mV, followed by a gradual increase to 230 mV after 50 hours of operation. Table 3 summarizes the changes in intrinsic overpotential vs time for MSb₂Oₓ and RuTiOₓ.

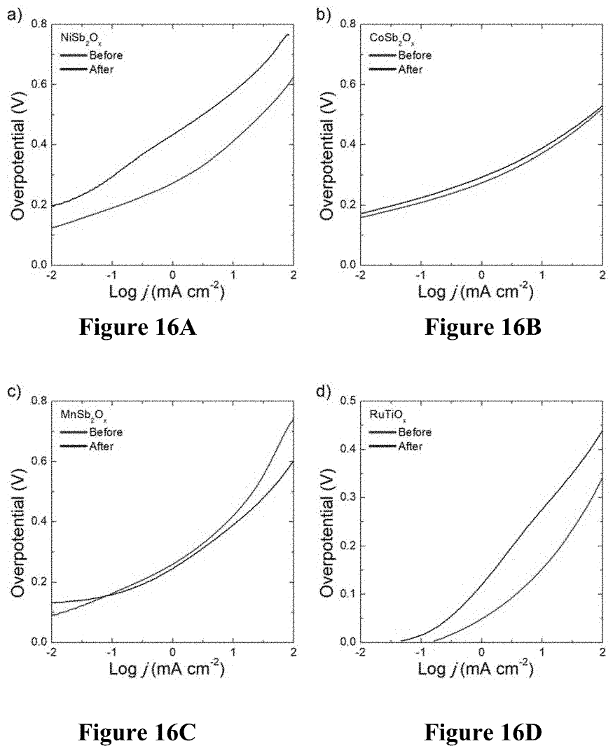

The Tafel behavior of NiSb₂Oₓ and RuTiOₓ films changed substantially after electrochemical testing (FIG. 16). NiSb₂Oₓ exhibited an initial Tafel slope of ˜94 mV dec⁻¹ that subsequently increased to ˜131 mV dec⁻¹. RuTiOₓ exhibited an initial Tafel slope of ˜69 mV dec⁻¹, which subsequently increased to ˜134 mV dec⁻¹ after 50 hours of operation. CoSb₂Oₓ and MnSb₂Oₓ exhibited Tafel slopes of ˜73 mV dec⁻¹ and ˜110 mV dec⁻¹, respectively, that were not substantially affected by operation. The Tafel slopes of NiSb₂Oₓ, MnSb₂Oₓ, and RuTiOₓ after operation closely matched with expectations for a Volmer-Heyrovsky mechanism, which predicts a ˜120 mV dec⁻¹ Tafel slope for a rate-determining Volmer step associated with the absorption of chloride anions. CoSb₂Oₓ exhibited a Tafel slope of ˜74 mV dec⁻¹, which is intermediate between expectations for the Volmer (120 mV dec⁻¹) and Heyrovsky (40 mV dec⁻¹) steps. Tafel slopes between 40-120 mV dec⁻¹ are associated with reaction rates being limited by at least two active sites, with one active site being limited by the Volmer step and another being limited by the Heyrovsky step.

Selectivity for Cl₂(g) vs O₂(g) Production:

The selectivity between chlorine evolution and oxygen evolution was estimated by measuring cyclic voltammograms of MSb₂Oₓ samples in 4.0 M NaCl(aq), pH=2 electrolyte and pH=2 H₂SO₄(aq) electrolyte. The current density observed in NaCl(aq) (j_{NaCl(aq)}) was attributed to two reactions, the chlorine evolution reaction (j_{CER}) and the oxygen evolution reaction (j_{OER}), whereas the current density observed in H₂SO₄ (j_{H2SO4(aq)}) was attributed to the oxygen-evolution reaction. The moles of chlorine and oxygen molecules produced over time were determined form the current densities using Faraday's constant (F, 96485.3389 C mol⁻¹), and the electrons required to obtain Cl₂ (2 mol e⁻ per mol Cl₂) and O₂ (4 mol e⁻ per mol O₂). The selectivity at 100 mA cm⁻² of current density in 4.0 M NaCl(aq), pH=2.0 electrolyte was estimated using the chlorine evolution and oxygen evolution current densities as shown on Equations 1-4.

$$\begin{matrix}{j}_{NaCl ( aq )} \tilde{=} {j}_{CER} + {j}_{OER} & ( 1 ) \\ {j}_{{H}_{2} {SO}_{4} ( aq )} \tilde{=} {j}_{OER} & ( 2 ) \\ {j}_{CER} \tilde{=} {j}_{NaCl ( aq )} - {j}_{{H}_{2} {SO}_{4} ( aq )} & ( 3 ) \\ S = \frac{\frac{d}{dt} {Cl}_{2}}{\frac{d}{dt} {O}_{2} + \frac{d}{dt} {Cl}_{2}} \tilde{=} \frac{\frac{{j}_{CER}}{2 F}}{\frac{{j}_{OER}}{4 F} + \frac{{j}_{CER}}{2 F}} & ( 4 )\end{matrix}$$

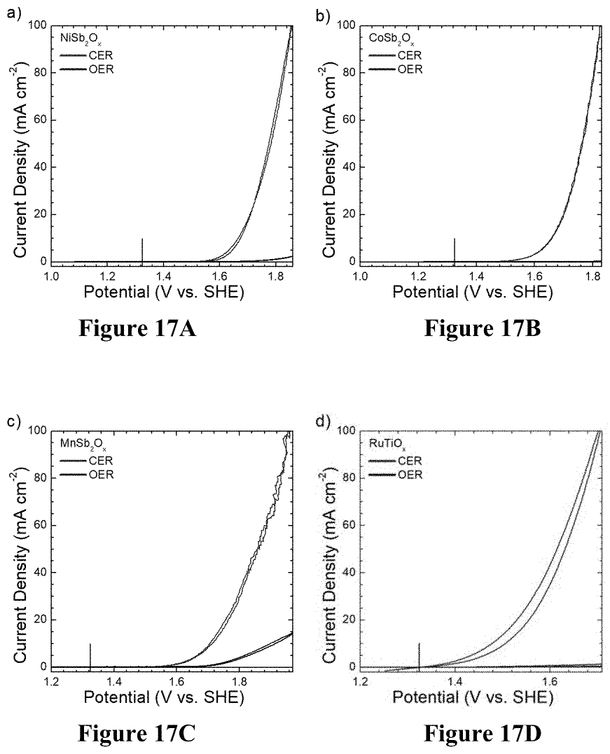

The selectivity of the electrocatalysts for the CER versus the OER was estimated by collecting cyclic voltammograms in pH=2.0 H₂SO₄(aq), with the current under these conditions being solely attributable to the OER. The OER current density at the same potential required to obtain j_{geo}=100 mA cm⁻² under chlorine evolution conditions was 2.2, 0.3, 13.6, and 0.8 mA cm⁻² for NiSb₂Oₓ, CoSb₂Oₓ, MnSb₂Oₓ, and RuTiOₓ, respectively (FIG. 17). Hence, CoSb₂Oₓ is expected to have the highest selectivity (˜99.8%), with RuTiOₓ (˜99.6%), NiSb₂Oₓ (˜98.9%), and MnSb₂Oₓ (˜92.7%) being less selective towards the CER relative to the OER. The production of chlorine was confirmed with colorimetric measurements using N,N-diethyl-p-phenylenediamine.

Surface composition as probed by XPS: X-ray photoelectron spectroscopy (XPS) scans were collected using a Kratos Axis NOVA (commercially available from Kratos Analytical, Manchester, UK) at a background pressure of <10⁻⁹ Torr. The x-ray source consisted of a monochromatic Al kα beam with an energy of 1486.6 eV. Survey scans were collected at 1.0 eV resolution, and high-resolution scans were collected at 0.05 eV resolution. The binding energy of the scans was corrected against the adventitious C is peak with a constant offset to obtain an adventitious C is peak energy of 284.8 eV. The M 2p spectra of Ni, Co, and Mn were fit using previously reported fitting parameters. The reported peak separations, FWHM ratios, and relative peak areas were used to fit the collected M 2p spectra. The XP spectrum of Sb 3d_{3/2} was used to determine the oxidation state of the surface Sb on MSb₂Oₓ samples. Literature values of Sb 3d_{3/2} peak binding energies for oxidation states of 3+, 3⁺/5⁺, and 5⁺ are 539.5 eV, 540.1 eV, and 540.4 eV respectively, for a C is peak binding energy of 284.8 eV.

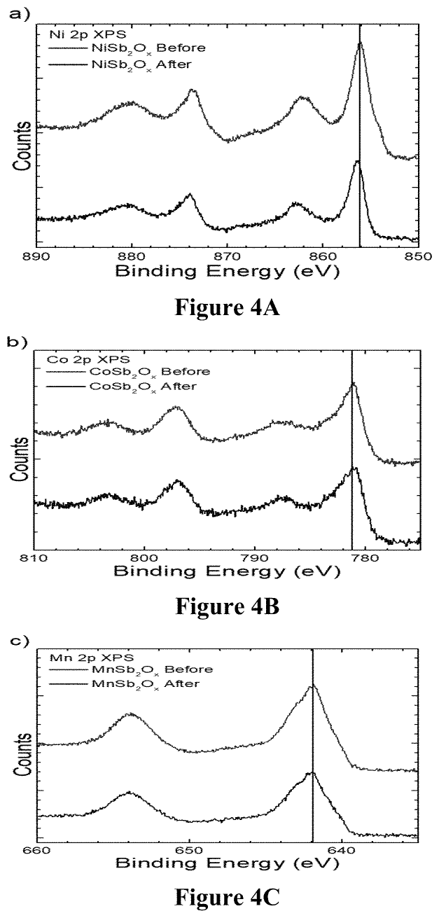

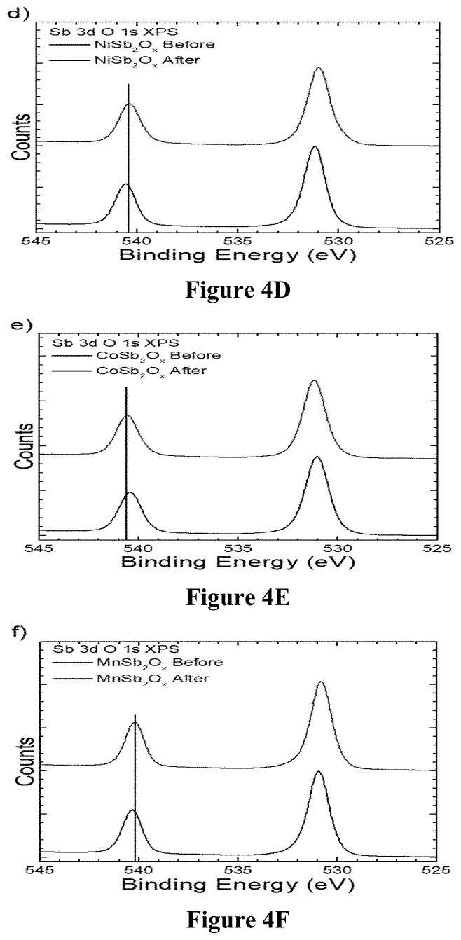

FIG. 4 shows high-resolution XP spectra of NiSb₂Oₓ, CoSb₂Oₓ, and MnSb₂Oₓ before and after chronopotentiometry at j_{geo}=100 mA cm⁻². The Ni 2p spectra of NiSb₂Oₓ exhibited a peak at ˜856.1 eV, with additional contributions at lower binding energies that are consistent with contributions from NiO and Ni(OH)₂. The peak shape at 856.1 eV is similar to that of Ni(OH)₂ but was located at ˜0.3 eV higher binding energy than the peak observed for Ni(OH)₂. The observed binding energy is intermediate to that of Ni(II) in NiCl₂ and Ni(OH)₂. XP spectra in the Cl, Ir, and Ru regions revealed no detectable Cl, Ir, and Ru before or after electrochemical operation. After electrochemical operation, NiSb₂Oₓ samples exhibited a narrow Ni 2p_{3/2} peak at 856.3±0.1 eV. Mutually similar Sb 3d_{3/2} binding energies were observed for NiSb₂Oₓ before (540.4±0.1 eV) and after (540.5±0.1 eV) electrochemical operation. The Sb binding energy is consistent with the samples containing Sb⁵⁺ as well as minor contributions from Sb³⁺. The surface stoichiometry of the NiSb₂Oₓ was 1:1.8±0.1 Ni:Sb prior to electrochemical operation and was 1:3.2±0.1 Ni:Sb after electrochemical operation, indicating that the surface became Sb rich. The catalyst surface coverage was determined by comparing the catalyst metal signal (Ni+Sb) to the overall metal signal of the catalyst and the substrate (Ni+Sb+Sn), with the signals corrected using the respective relative sensitivity factors. The catalyst coverage was 100% of the surface in both cases.

Before and after electrochemical operation, CoSb₂Oₓ samples exhibited a narrow Co 2p_{3/2} XPS peak at 781.2±0.1 eV. The peak shape of Co in CoSb₂Oₓ was similar to that of Co in Co(OH)₂, but with a ˜0.5 eV higher binding energy. The observed binding energy is between that of hydrated CoCl₂ and Co(OH)₂, indicating that Co is in the 2+ oxidation state at the surface of the CoSb₂Oₓ films. The XPS measurements indicate that the oxidation state of Co did not irreversibly change as a result of electrochemical operation. Wide scan XP spectra showed no detectable Cl, Ir, or Ru on the electrodes. The Sb3d_{3/2} binding energy was 540.6±0.1 eV prior to electrochemical operation and 540.3±0.1 eV after electrochemical operation. The XPS measurements indicate that Sb was present in the 5+ oxidation state prior to electrochemical operation and was in a mixed 5+/3+ oxidation state after electrochemical operation. The surface stoichiometry of CoSb₂Oₓ was 1:4.0±0.1 Co:Sb prior to electrochemical operation and was 1:4.5±0.1 Co:Sb after electrochemical operation, indicating minor enrichment of Sb at the surface. The CoSb₂Oₓ surface catalyst coverage was 100% before and after electrochemical operation.

The MnSb₂Oₓ samples exhibited a Mn 2p_{3/2} XPS peak at a binding energy of 641.9±0.1 eV before electrochemical operation and 642.0±0.1 eV after electrochemical operation. The binding energies are comparable to Mn in the 2+ oxidation state in MnCl₂. Wide scan XP spectra indicated no detectable Cl, Ir, or Ru on the surface. The Sb 3d_{3/2} peak exhibited a binding energy of 540.2±0.1 eV prior to electrochemical operation and 540.3±0.1 eV after electrochemical operation. The Sb 3d spectra indicated that Sb was present in both the 5+ and 3+ oxidation states before and after electrochemical operation. The surface stoichiometry of MnSb₂Oₓ was 1:2.0±0.1 Mn:Sb prior to electrochemical operation and 1:2.7±0.2 Mn:Sb after electrochemical operation, indicating surface enrichment of Sb after chlorine evolution. The surface coverage of MnSb₂Oₓ was 98.8±0.4% prior to electrochemical operation and 96.8±0.1% after electrochemical operation, indicating partial exposure of the electrocatalyst substrate after chlorine evolution. Table 4 summarizes the observed binding energies of the MSb₂Oₓ samples and also presents a comparison of the binding energies to literature values. More specifically, Table 4 presents a summary of XPS binding energies observed for example MSb₂Oₓ samples before and after electrochemical operation and literature values for various M and Sb compounds.

TABLE 4

| | M 2p_{3/2} Binding | Sb 3d_{5/2} Binding | |
|---|---|---|---|
| | Energy | Energy | |
| Material | (eV) | (eV) | Reference |
| NiSb₂Oₓ | 856.1 ± 0.1 | 540.4 ± 0.1 | — |
| (before) | | | |
| NiSb₂Oₓ | 856.3 ± 0.1 | 540.5 ± 0.1 | — |
| (after) | | | |
| CoSb₂Oₓ | 781.2 ± 0.1 | 540.6 ± 0.1 | — |
| (before) | | | |
| CoSb₂Oₓ | 781.2 ± 0.1 | 540.3 ± 0.1 | — |
| (after) | | | |
| MnSb₂Oₓ | 641.9 ± 0.1 | 540.2 ± 0.1 | — |
| (before) | | | |
| MnSb₂Oₓ | 642.0 ± 0.1 | 540.3 ± 0.1 | — |
| (after) | | | |
| NiCl₂ | 856.77 | — | ¹⁰ |
| Ni(OH)₂ | 855.80 | — | ¹⁰ |
| CoCl₂•(H₂O)₆ | 782.1 | — | ¹¹ |
| Co(OH)₂ | 780.65 | — | ⁶ |
| MnCl₂ | 642.0 | — | ¹² |
| Sb₂O₃ | — | 539.7 | ⁷ |
| Sb₂O₄ | — | 540.3 | ⁷ |
| Sb₂O₅ | — | 560.6 | ⁷ |

Table 5 summarizes the roughness factor, overpotential, stoichiometry, and catalyst loss of the catalysts studied herein after different durations of galvanostatic operation. More specifically, Table 5 provides a summary of roughness factor, overpotential at 100 mA cm⁻², surface composition, and catalyst loss over time for NiSb₂Oₓ, CoSb₂Oₓ, MnSb₂Oₓ, and RuTiOₓ. Final catalyst loss and roughness factor were determined at 50 hours. Final overpotential data is at 90 hours for CoSb₂Oₓ, MnSb₂Oₓ, and RuTiOₓ, and at 65 hours for NiSb₂Oₓ.

TABLE 5

| Time | Property | NiSb₂Oₓ | CoSb₂Oₓ | MnSb₂Oₓ | RuTiOₓ |
|---|---|---|---|---|---|
| Initial | RF | 1.1 ± 0.1 | 6.6 ± 2.5 | 9.0 ± 5.2 | 8.8 ± 3.9 |
| | η_{cv} (mV) | 565 ± 45 | 502 ± 16 | 674 ± 88 | 328 ± 53 |
| | η_{g} (mV) | 543 | 520 | 860 | 330 |
| | M:Sb bulk | 1:1.6 | 1:2.2 | 1:1.7 | — |
| | M:Sb surf. | 1:1.8 | 1:4.0 | 1:2.0 | — |
| After 2 h | RF | 2.1 | 4.3 | 10.7 | 6.1 |
| | η_{cv} (mV) | 524 | 550 | 641 | 380 |
| | η_{g} (mV) | 511 | 560 | 702 | 400 |
| | M loss (nmol cm⁻²) | 109 | 0.53 | 21 | — |
| | Sb loss (nmol cm⁻²) | 5.6 | 0.44 | 3.0 | — |
| After | RF | 11 | 7.6 | 25.0 | 6.6 |
| 50-90 h | η_{cv} (mV) | 856 | 533 | 592 | 497 |
| | η_{g} (mV) | 853 | 545 | 595 | 540 |
| | M:Sb surf. | 1:3.2 | 1:4.5 | 1:2.7 | — |
| | M loss (nmol cm⁻²) | 382 | 1.79 | 192 | — |
| | Sb loss (nmol cm⁻²) | 45 | 2.56 | 185 | — |

Catalyst Intrinsic Activity:

The initial intrinsic activity measurements of TMAs under chlorine evolution indicate an activity trend of NiSb₂Oₓ>CoSb₂Oₓ>MnSb₂Oₓ. Further improvements in the activity of TMAs towards chlorine evolution may be achieved via solid solutions, as has been demonstrated for OER electrocatalysts and/or by use of other transition metals in the SbOₓ framework. Notably, CoSb₂Oₓ had the highest CER activity after extended operation (FIGS. 2 and 17). While the CoSb₂Oₓ catalyst had an initial intrinsic overpotential that was ˜190 mV higher than RuTiOₓ, this difference decreased to ˜140 mV after 50 hours of chronopotentiometry, due to the intrinsic overpotential of RuTiOₓ increasing (˜1.3 mV h⁻¹) while the CoSb₂Oₓ intrinsic overpotential remained constant after an initial increase (FIG. 3B). The high stability of the electrochemical activity of CoSb₂Oₓ relative to RuTiOₓ suggests that CoSb₂Oₓ electrodes may have active electrocatalytic CER lifetimes exceeding those of RuTiOₓ.

During chlorine evolution, the surface composition of the TMAs changed, and correlated with changes in the intrinsic activity of the catalyst films. As indicated by XPS, NiSb₂Oₓ and MnSb₂Oₓ exhibited surface compositions that were very similar to their bulk composition (˜1:2 M:Sb), but CoSb₂Oₓ exhibited substantial initial surface enrichment of Sb (1:4 Co:Sb) despite having a bulk composition of ˜1:2 M:Sb (FIG. 4, Table 1).

The intrinsic overpotential of NiSb₂Oₓ films initially decreased by ˜5% during operation, followed by an increase of ˜110%, i.e. ˜300 mV (FIG. 3). While the surface composition of the NiSb₂Oₓ was similar to its bulk composition (˜1:2 M:Sb), the initial surface was covered by multiple Ni species, such as NiSb₂O₆, NiOₓ and Ni(OH)₂ (FIG. 4A). NiO and Ni(OH)₂ are expected to be readily removed from the surface due to thermodynamically favored dissolution processes under the operating conditions. Loss of NiOₓ and Ni(OH)₂ in the first hour of operation could explain the initial improvement in catalytic activity, if these species had a detrimental effect on the activity. After 50 hours of operation, NiSb₂Oₓ exhibited substantial surface enrichment of Sb, as indicated by the 80% increase of Sb relative to Ni (FIGS. 4A, 4D). The Ni in NiSb₂Oₓ exhibited a similar electronic state before and after electrochemical operation, as indicated by the Ni 2p XPS data, suggesting that the surface Ni remained in a NiSb₂O₆ lattice and did not undergo conversion to Ni oxides or (oxy)hydroxides. However, the oxidation state of Sb changed after electrochemical operation, suggesting that the surface NiSb₂O₆ became partially covered with SbOₓ in the 3+ oxidation state.

The intrinsic overpotential of MnSb₂Oₓ increased by ˜85 mV in the first hour of operation but increased by only another 20 mV in the next 50 hours. The oxidation states of both Mn and Sb did not change substantially after electrochemical operation (FIGS. 4B, 4E). However, the surface of the MnSb₂Oₓ became Sb rich, as indicated by the 39% increase in Sb at the surface compared to Mn as measured by XPS. The increase in Sb at the surface, without a substantial change in binding energy, suggests that Sb remained in the 5+ oxidation state. The substantially smaller change in overpotential after 50 hours for MnSb₂Oₓ (Δηᵢ=134 mV) as compared to NiSb₂Oₓ (Δηᵢ=287 mV) might be due to a lower surface coverage of SbOₓ species in conjunction with retention of Sb in the 5+ oxidation state (FIGS. 3 and 4). The surface of CoSb₂Oₓ differed substantially from the surface of NiSb₂Oₓ or MnSb₂Oₓ.

CoSb₂Oₓ exhibited substantial initial surface enrichment of Sb (1:4 Co:Sb) prior to electrochemical operation in contrast to both NiSb₂Oₓ and MnSb₂Oₓ that had an initial surface M:Sb ratio close to their bulk stoichiometry of ˜1:2. The CoSb₂Oₓ exhibited a minimal increase in surface Sb (1:4.5 Co:Sb) after electrochemical operation (˜13%), again in contrast to NiSb₂Oₓ and MnSb₂Oₓ whose Sb surface enrichment after electrochemical operation increased ˜80%, and ˜39%, respectively, However, in all cases after electrochemical operation the surfaces were significantly enriched in Sb relative to the transition metal. As opposed to the NiSb₂Oₓ and MnSb₂Oₓ electrodes, the CoSb₂Oₓ electrode exhibited a minimal change in intrinsic overpotential after 50 hours (Δηᵢ=48 mV), which correlates with the minimal change in Sb enrichment at the surface. The initial oxidation states of Co and Sb at the surface were 2+ and 5+, in accord with expectations for stoichiometric CoSb₂O₆ (FIG. 4). After electrochemical testing, CoSb₂Oₓ exhibited a decrease of 0.3 eV in Sb 3d_{5/2} binding energy, whereas NiSb₂Oₓ and MnSb₂Oₓ both exhibited an increase in the binding energy of Sb 3d_{5/2} (ΔE=0.1 eV). The decrease in binding energy for CoSb₂Oₓ suggests that a substantial portion of the surface Sb atoms were reduced from Sb⁵⁺ to Sb³⁺. Cyclic voltammetry data were collected at more negative potentials than thermodynamic potential for chlorine evolution, and cathodic current was observed at such potentials (FIG. 2B). Further studies to determine the catalytically active site on the surface could determine if the transition metals act primarily as catalytically active sites or primarily act to promote the activity of SbOₓ, which would allow further elucidation of the electrocatalytic role of the Sb oxidation state.

Comparison of Activity to Other CER Electrocatalysts: Previous studies of chlorine evolution catalysts have included Co₃O₄, which exhibits η˜620 mV at j_{geo}=100 mA cm⁻², with an estimated catalyst roughness factor of >3,000. Nanostructured RuO₂—TiO₂ electrodes exhibit η˜710 mV at j_{geo}=250 mA cm⁻², with an estimated roughness factor of 390. Ir_{0.7}Ta_{0.3}O_{y} films exhibit η>1,000 mV at j_{geo}=30 mA cm⁻² in pH=7, 50 mM NaCl(aq) electrolyte. Mesoporous Ru/TiO₂ dimensionally stable anodes exhibit η˜650 mV at j_{geo}=100 mA cm⁻² in 4.0 M NaCl(aq), pH=3.0 electrolyte. The ˜540 mV galvanostatic overpotential at j_{geo}=100 mA cm⁻² reported herein for RuTiOₓ between 85-90 hours of operation is comparable to previous reports of noble metal oxides for chlorine evolution (FIG. 2A). CoSb₂Oₓ exhibits a galvanostatic overpotential of ˜545 mV at j_{geo}=100 mA cm⁻², which is lower than some previous reports for noble metal oxides and is comparable to the overpotential observed herein for RuTiOₓ after extended operation (FIG. 2A). The catalyst loading and roughness factor used herein were both relatively low, to facilitate determination of the intrinsic properties of the electrocatalysts. Consequently, the overpotential of the TMAs could be improved further by increasing the catalyst loading and roughness, to expose additional catalytically active sites without changing the geometric area of the electrode. Due to the deactivation of RuTiOₓ during chronopotentiometry and the comparatively high electrochemical stability of CoSb₂Oₓ, after 85 hours of operation CoSb₂Oₓ exhibited a galvanostatic overpotential only ˜5 mV higher that of RuTiOₓ (˜540 mV). This behavior suggests that CoSb₂Oₓ may constitute a promising alternative to RuTiOₓ for the chlor-alkali process and other processes that require the CER. Co and Sb are substantially more abundant than Ru, and their annual molar production rates are over 5,000 times higher than Ru. The high abundance of both Co and Sb relative to Ru is reflected in the market price of these elements, which reflects a substantially lower price per mole of metals for CoSb₂Oₓ (˜$2 USD mol⁻¹) compared to the price per mol for the commercially used Ru_{0.3}Ti_{0.7}Oₓ (˜$153 USD mol⁻¹) catalyst.

Catalyst Stability:

Under CER conditions, the chemical stability of the TMA's decreased in the order CoSb₂Oₓ>MnSb₂Oₓ>NiSb₂Oₓ. CoSb₂Oₓ exhibited the lowest dissolution rate, with <0.6 nm of Co and <0.6 nm of Sb lost from the surface after 50 hours of operation (FIG. 14B). Possible explanations for the appearance of M and Sb in the electrolyte include dissolution of oxide species that did not form the stable MSb₂O₆ phase, and/or chemically or electrochemically driven dissolution processes. Additionally, mechanical detachment of MSb₂O₆ particles could lead to changes in the catalyst loading that cannot be detected with ICP-MS. The small amount of dissolved Co and Sb (˜4×10⁻⁹ mol cm⁻²) for CoSb₂Oₓ, compared to the charge passed during the stability experiments (˜1.8×10⁴ C cm⁻²), suggests a turnover number of >2×10⁷, indicating that faradaic dissolution pathways are unlikely to be dominant. The high chemical and electrochemical stability of CoSb₂Oₓ, as indicated by minimal changes in catalyst morphology, intrinsic overpotential, and surface oxidation, indicate that CoSb₂Oₓ and possibly other TMAs could be viable materials for chlorine evolution in devices requiring abundant and stable electrocatalysts under industrially relevant operational conditions.

NiSb₂Oₓ, CoSb₂Oₓ, and MnSb₂Oₓ were found to be active chlorine evolution catalysts for >60 hours at j_{geo}=100 mA cm⁻² in 4.0 M NaCl(aq), pH=2.0 electrolyte. CoSb₂Oₓ exhibited the highest stability and selectivity among the TMAs disclosed herein, with <1 nm of metals lost after extended electrochemical operation. After 90 hours of operation, the galvanostatic overpotential of CoSb₂Oₓ at j_{geo}=100 mA cm⁻² was comparable to that of dimensionally stable RuTiOₓ.

The foregoing description is illustrative and not restrictive. Although certain exemplary embodiments have been described, other embodiments, combinations and modifications involving the disclosure will occur readily to those of ordinary skill in the art in view of the foregoing teachings. Therefore, other embodiments are within the scope of the following claims.

What is claimed is:

1. A method of manufacturing an electrocatalyst usable for an electrochemical reaction, comprising:
depositing an antimony-doped tin oxide (ATO) film onto a substrate;
depositing a metallic film onto the ATO film; and
annealing the ATO film and the metallic film to form a metal oxide film containing a crystalline transition metal antimonite (TMA).

2. The method of claim 1, wherein the TMA is selected from the group consisting of NiSb₂Oₓ, CoSb₂Oₓ, and MnSb₂Oₓ, where x is greater than zero and less than or equal to six.

3. The method of claim 1, wherein the TMA is selected from the group consisting of NiSb₂O₆, CoSb₂O₆, and MnSb₂O₆.

4. The method of claim 1, wherein the metallic film includes a metal or alloy selected from the group consisting of Ni, Co, Mn, Sb, NiSb₂, CoSb₂, and MnSb₂.

5. The method of claim 1, wherein depositing the metallic film onto the ATO film includes sputtering a metal onto the ATO film.

6. The method of claim 1, wherein depositing the metallic film onto the ATO film includes co-sputtering a plurality of metals onto the ATO film.

7. The method of claim 1, wherein the metallic film includes a transition metal and antimony, where the transition metal (M) loading and stoichiometry to antimony (Sb) is a bulk M:Sb atomic ratio of approximately 1:2.

8. The method of claim 1, wherein the metallic film includes a transition metal load of 375-483 nmol cm⁻².

9. The method of claim 1, wherein the metallic film includes an antimony load of 709-820 nmol cm⁻².

10. The method of claim 1, wherein annealing includes increasing the temperature of at least the deposited metallic and ATO films to about 750° C. and holding the temperature of the deposited metallic and ATO films at about 750° C. for approximately 6 hours.

11. The method of claim 10, wherein the temperate is increased at a ramp rate of about 10° C. min⁻¹.

12. The method of claim 1, wherein depositing the ATO film includes using spray pyrolysis to deposit the ATO onto the substrate.

13. The method of claim 1, wherein the electrochemical reaction is a chlorine evolution reaction.

14. An electrocatalyst made by the method of claim 1.

15. An electrocatalyst, comprising:
a metal oxide film containing a crystalline transition metal antimonite (TMA).

16. The electrocatalyst of claim 15, further comprising a conductive substrate that includes an antimony-doped tin oxide (ATO) film, the metal oxide film being deposited on the conductive substrate.

17. The electrocatalyst of claim 15, wherein the TMA is selected from the group consisting of NiSb₂Oₓ, CoSb₂Oₓ, and MnSb₂Oₓ, where x is greater than zero and less than or equal to six.

18. The electrocatalyst of claim 17, wherein the TMA is selected from the group consisting of NiSb₂O₆, CoSb₂O₆, and MnSb₂O₆.

19. The electrocatalyst of claim 15, included in an electrode.

20. The electrocatalyst of claim 19, wherein the electrode is used for a chlorine evolution reaction (CER).
